(19) United States
(12) Patent Application Publication
(10) Pub. No.: US 2025/0294920 A1
(43) Pub. Date: Sep. 18, 2025

(54) METHOD FOR FORMING A LAYER WITH THE BASIS OF A DIELECTRIC MATERIAL ON A LAYER WITH THE BASIS OF AN ETCHED III-V MATERIAL

(71) Applicants: COMMISSARIAT A L'ENERGIE ATOMIQUE ET AUX ENERGIES ALTERNATIVES, Paris (FR); UNIVERSITE GRENOBLE ALPES, Saint Martin D'Heres (FR); INSTITUT POLYTECHNIQUE DE GRENOBLE, Grenoble (FR); CENTRE NATIONAL DE LA RECHERCHE SCIENTIFIQUE, Paris (FR)

(72) Inventors: Nicolas POSSEME, Grenoble Cedex 09 (FR); Patricia PIMENTA BARROS, Grenoble Cedex 09 (FR); Simon RUEL, Grenoble Cedex 09 (FR); Bassem SALEM, Sassenage (FR); Sarah BOUBENIA, Grenoble (FR)

(73) Assignees: COMMISSARIAT A L'ENERGIE ATOMIQUE ET AUX ENERGIES ALTERNATIVES, Paris (FR); UNIVERSITE GRENOBLE ALPES, Saint Martin D'Heres (FR); INSTITUT POLYTECHNIQUE DE GRENOBLE, Grenoble (FR); CENTRE NATIONAL DE LA RECHERCHE SCIENTIFIQUE, Paris (FR)

(21) Appl. No.: 18/861,951

(22) PCT Filed: May 4, 2023
(86) PCT No.: PCT/EP2023/061856

§ 371 Date: Oct. 31, 2024

(30) Foreign Application Priority Data
May 5, 2022 (FR) 2204258

(51) Int. Cl. H10H 20/01; H01L 21/02

(52) U.S. Cl. CPC H10H 20/0137; H01L 21/02274; H01L 21/0228; H01L 21/02458; H01L 21/0254

(57) ABSTRACT

A method for forming a layer based upon a dielectric material on a layer based upon an etched III-V material includes providing at least one III-V layer base upon a III-V material, preferably III-N, having a front face. The method also includes etching at least one part of the III-V layer from the front face, so as to expose an etched surface of the III-V layer; exposing at least the etched surface to a plasma treatment of O₂ or of N₂, this step being carried out at a temperature Tₜᵣₑₐₜₘₑₙₜ with Tₜᵣₑₐₜₘₑₙₜ<100° C., and depositing a layer based upon a dielectric material at least on the etched surface.

### TECHNICAL FIELD OF THE INVENTION

The present invention relates to the formation of a layer with the basis of a dielectric material on a layer with the basis of an etched III-V material, such as etched GaN. It thus falls into the manufacturing of devices comprising an interface between a III-N material and dielectric material. It has, for example, a particularly advantageous application in the field of power electronics, such as transistors integrating one or more III-N material layers.

### PRIOR ART

Avoiding energy waste and increasing needs are pushing manufacturers of microelectronic devices to improve the yields and the performance of their electric energy conversion systems. Currently, conversion circuits are manufactured silicon-based and much research has been carried out to develop architectures, with the aim of increasing yield and conductivity. However, these known devices arrive at the theoretical limits of silicon and novel solutions are considered. These solutions are based on using III-V materials such as GaN. Such is the case, for high-electron-mobility transistors (HEMT).

Manufacturing these types of devices requires the carrying out of numerous steps of etching in III-V materials followed by depositions of dielectric layers on etched zones. Yet, the etching steps can highly degrade the chemical and electric properties of the etched materials. It ensues that the interface made between the III-V material and the dielectric often has degraded electronic properties. For example, plasma etchings induce structural defects altering the quality of the interfaces between the etched layer and the dielectric layer. The electric properties of these interfaces and, consequently, electronic components, are degraded.

It is known from the prior art to resort to etching methods which are intrinsically less damaging for the quality of the etched layer. Cyclic etching techniques, in particular, techniques known as “atomic layer etching” or ALE, make it possible to obtain minimally damaged etched layers having good electric properties. However, current ALE techniques are very time-consuming and highly impact productivity. In addition, they are sometimes difficult to implement, as it is necessary to be in the often narrow energy range, enabling a both selective and complete removal of the layer that it sought to be etched.

There is therefore a need consisting of providing a solution to improve the productivity of the formation of a dielectric layer on an etched III-V material layer and without impacting the quality of the interface made.

### SUMMARY OF THE INVENTION

To achieve this aim, according to an embodiment, a method is provided for forming a layer with the basis of a dielectric material on a layer with the basis of an etched III-V material. The method comprises at least the following steps:
Providing at least one layer with the basis of a III-V material, preferably III-N, called III-V layer, having a front face,
Etching at least one part of the III-V layer from the front face, so as to expose a surface of the III-V layer called etched surface,
Exposing at least the etched surface to a plasma treatment of O₂, of N₂, or of a mixture of O₂ and of N₂, this step being carried out at a temperature Tₜᵣₑₐₜₘₑₙₜ with Tₜᵣₑₐₜₘₑₙₜ<100° C.,
Depositing a layer with the basis of a dielectric material, called dielectric layer, at least on the etched surface.

The plasma treatment step implemented in the method according to the invention makes it possible to greatly improve the quality of the III-V material layer, typically etched GaN. The low-temperature work in particular makes it possible to obtain a highly stabilised etched GaN layer, thus making it possible to facilitate and accelerate the handling of the samples, which results in an increase of productivity. The samples must indeed be moved from one reactor to another, for example, from the reactor where the plasma treatment has taken place at the reactor where the deposition of the Al₂O₃ dielectric layer has taken place, for example. In the scope of the development of the present invention, it has been noted that with higher temperatures, the III-N material layer is less stable, which poses problems in terms of robustness of the method. Furthermore, in the scope of the development of the present invention, it has unexpectedly been observed that this lowering of the temperature leads to an interface quality between the etched III-N material and the dielectric material, which is better than what was foreseeable. On the contrary, in this context, a person skilled in the art would have encouraged to apply high temperatures to recrystalise the III-V material located on the surface, and which is altered by etching.

The improvement of the quality of the etched GaN layer, itself induces a high improvement of the quality of the etched GaN/dielectric interface, in particular from the standpoint of its electric properties.

The method according to the invention thus makes it possible to considerable improve productivity with respect to an ALE-type solution, while offering a very satisfactory interface quality. It is, however, possible that the method according to the invention is used together with an ALE-type etching.

It must be noted that the treatments subsequent to a step of depositing non-etched epitaxially grown GaN are not adapted to the treatment of an etched GaN layer, or are at least a lot less effective. Indeed, the surface of a non-etched epitaxially grown GaN layer is relatively stable, as the layer has generally spent a significant amount of time, often a few hours to a few months, in the air. The stoichiometry of the epitaxially grown GaN layer is stabilised, which makes the surface of the layer minimally reactive, contrary to the surface of an etched GaN layer. Thus, the strategy of applying a plasma treatment proposed in the present application to chemically modify the surface of the GaN, and thus improve the quality of the interface with the dielectric will have minimal effects on the epitaxially grown GaN surfaces. On the non-etched epitaxially grown surfaces, the plasma treatment rather constitute cleaning strategies and do not enable the structural reconstruction that the method according to the invention used on an etched GaN layer enables.

Furthermore, a method is provided for producing a microelectronic device comprising the formation of a layer with the basis of a dielectric material on a layer with the basis of an etched III-V material, by implementing the formation method mentioned above, the microelectronic device being taken from among a transistor and an LED.

In addition, a method is provided for producing a microelectronic device according to the production method mentioned above, in which:
the microelectronic device is a transistor,
the etching of the III-V layer is carried out, so as to produce a trench in the etched III-V material,
the deposition of the layer with the basis of a dielectric material is carried out on at least one part of the etched surface of the trench, so as to form a gate dielectric, and comprising, after the formation of the dielectric layer, the following step:
filling the trench to define at least one gate of the transistor.

By microelectronic device, this means any type of device produced with microelectronic means. These devices include, in particular in addition to devices with a purely electronic purpose, micromechanical or electromechanical devices (MEMS, NEMS, etc.), as well as optical or optoelectronic devices (LED, MOEMS, etc.). This can be a device intended to ensure an electronic, optical, mechanical function, etc. This can also be an intermediate product only intended for the production of another microelectronic device.

Also, a method is provided for producing a transistor, the method comprising the following steps:
forming a layer with the basis of a dielectric material on a layer with the basis of an etched III-V material by implementing the formation method mentioned above. The etching of the III-V layer is carried out, so as to produce a trench in the etched III-V material. The deposition of the layer with the basis of a dielectric material is carried out on at least one part of the etched surface of the trench, so as to form a gate dielectric.
filling the trench to define at least one gate of the transistor.

Also, a method is provided for producing a transistor comprising the following steps:
Providing at least one layer with the basis of a III-V material, preferably III-N, called III-V layer, having a front face,
Etching at least one trench in the III-V layer from the front face and through the mask, so as to expose a surface of the III-V layer called etched surface,
Exposing at least the etched surface to a plasma treatment of O₂ or of N₂, this step being carried out at a temperature Tₜᵣₑₐₜₘₑₙₜ with Tₜᵣₑₐₜₘₑₙₜ<100° C.,
Depositing a layer with the basis of a dielectric material, called dielectric layer, at least on one part of the etched surface of the trench, so as to form a gate dielectric,
Filling the trench to define at least one gate of the transistor.

This type of transistor has an improved interface between the III-V layer and the dielectric layer. Thus, this method has an improved productivity, while enabling the transistor to achieve high performance.

### BRIEF DESCRIPTION OF THE FIGURES

The aims, objectives, as well as the features and advantages of the invention, will best emerge from the detailed description of an embodiment of the latter which is illustrated by the following accompanying drawings, in which:

FIGS. 1A to 1G illustrate the steps of a method according to one of the embodiments of the invention. FIG. 1A illustrates the provision of a layer with the basis of a III-V material called III-V layer.

FIG. 1B illustrates the deposition of an optional masking layer surmounting the III-V layer.

FIG. 1C represents the formation of openings in the masking layer, in order to constitute an etching mask on the III-V layer.

FIG. 1D illustrates a step of etching the III-V layer making it possible to update a surface called etched surface of the III-V layer.

FIG. 1E illustrates a step of exposing the etched surface to a plasma treatment, featured by a set of arrows oriented towards the etched surface.

FIG. 1F represents the deposition of a dielectric layer on the etched surface.

FIG. 1G illustrates the removal of the optional mask.

FIG. 2A represents a capacitance-voltage feature (C-V feature or also C-V profiling) of a MOS (metal oxide semiconductor) capacitance, manufactured according to a known method of the prior art.

FIG. 2B represents a C-V feature of a MOS capacitance manufactured according to an embodiment of the method according to the invention.

FIG. 3 summarises the different steps of an example of a formation method according to the invention.

FIG. 4 is a graph illustrating the C-V features of MOS capacitances produced according to an embodiment of the invention, with a treatment temperature for one of 40° C. and for the other, of 60° C.

FIG. 5A is a graph representing the value of the flat band voltage of MOS capacitances produced according to an embodiment of the invention, with a treatment temperature for one of 40° C. and for the other, of 60° C.

FIG. 5B is a graph representing the value of the hysteresis of MOS capacitances produced according to an embodiment of the invention, with a treatment temperature for one of 40° C. and for the other, of 60° C.

The drawings are given as examples and are not limiting of the invention. They constitute principle schematic representations, intended to facilitate the understanding of the invention and are not necessarily to the scale of practical applications. In particular, the thicknesses of the different layers are not representative of reality.

### DETAILED DESCRIPTION OF THE INVENTION

Before starting a detailed review of embodiments of the invention, below, optional features are stated, which can optionally be used in association or alternatively:

According to an embodiment, the etching step and the plasma treatment step are carried out in one same reactor.

According to an example, Tₜᵣₑₐₜₘₑₙₜ>40° C.

According to an example, Tₜᵣₑₐₜₘₑₙₜ<80° C.

According to an example, the plasma treatment step has a duration tₜᵣₑₐₜₘₑₙₜ, with tₜᵣₑₐₜₘₑₙₜ<5 min, that is tₜᵣₑₐₜₘₑₙₜ<300 s, and preferably tₜᵣₑₐₜₘₑₙₜ<2 min, that is tₜᵣₑₐₜₘₑₙₜ<120 s.

According to an embodiment, the method comprises, before the step of depositing the dielectric layer, a wet cleaning step.

According to an embodiment, the step of depositing the dielectric layer is carried out under vacuum.

According to an example, the etching step comprises a chlorine plasma etching.

According to an example, the etching step comprises at least one ALE-type etching cycle.

According to an example, the etching is carried out, so as to etch a III-V material thickness greater than 100 nm (10⁻⁹ metres), preferably greater than 500 nm, preferably greater than 1 μm (10⁻⁶ metres), preferably greater than 3 μm.

According to an example, the plasma treatment step is carried out under a zero bias voltage V_{bias}.

According to an example, the plasma treatment step is carried out by injecting a flow of O₂, of N₂ or of a mixture of O₂ and of N₂ having a mass flow D_{flow} of between 50 sccm and 1000 sccm, preferably between 100 sccm and 500 sccm.

According to an example, the plasma treatment step is carried out by injecting a flow of O₂, of N₂ or of a mixture of O₂ and of N₂ generated by a power source P_{source} of between 100 W and 4000 W, preferably between 300 W and 1000 W.

According to an example, the III-V material is one from among GaN and AlGaN.

According to an example, the dielectric material is one from among AlN, Al₂O₃ and HfO₂.

It is specified that, in the scope of the present invention, the terms “on”, “surmounts”, “covers”, “underlying”, “opposite” and their equivalents do not necessarily mean “in contact with”. Thus, for example, the deposition, the transfer, the bonding, the assembly or the application of a first layer on a second layer, does not compulsorily mean that the two layers are directly in contact with one another, but means that the first layer covers at least partially the second layer by being, either directly in contact with it, or by being separated from it by at least one other layer or at least one other element.

A layer can moreover be composed of several sublayers of one same material or of different materials.

By a substrate, a layer, a device “with the basis” of a material M, this means a substrate, a layer, a device comprising this material M only, or this material M and optionally other materials, for example, alloy elements, impurities or doping elements. Thus, a material with the basis of a III-N material can comprise a III-N material added with dopants. Likewise, a GaN-based layer typically comprises GaN and AlGaN or InGaN alloys.

The term “III-V material” makes reference to a semiconductor composed of one or more elements of the III column and of the V column of Mendeleev's periodic table. Among the elements of the III column, there are boron, gallium, aluminium or also indium. The V column contains, for example, nitrogen, arsenic, antimony and phosphorus.

By “selective etching with respect to” or “etching having a selectivity with respect to”, this means an etching configured to remove a material A or a layer A with respect to a material B or a layer B, and having an etching speed of the material A greater than the etching speed of the material B. The selectivity is the ratio between the etching speed of the material A over the etching speed of the material B. The selectivity between A and B is referenced SA:B.

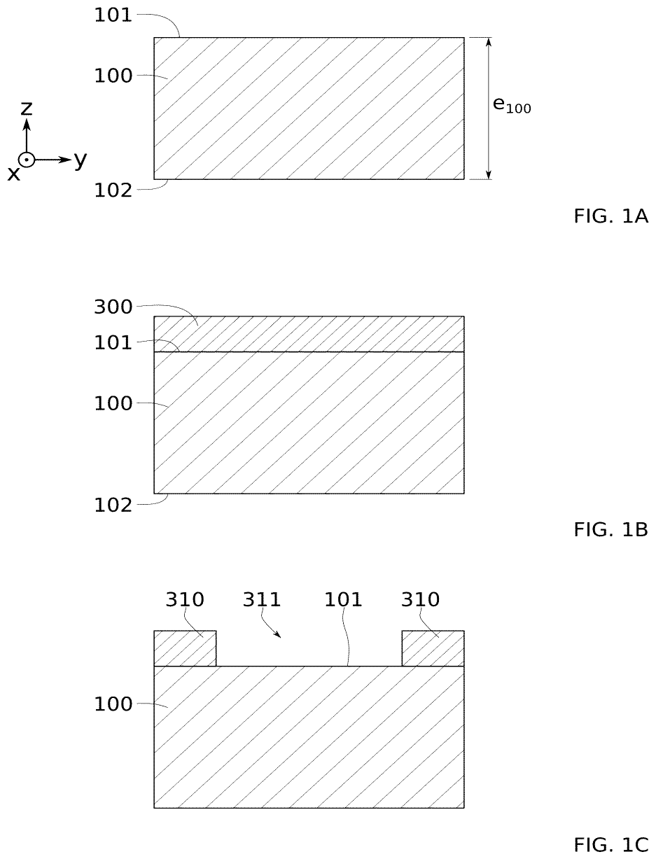

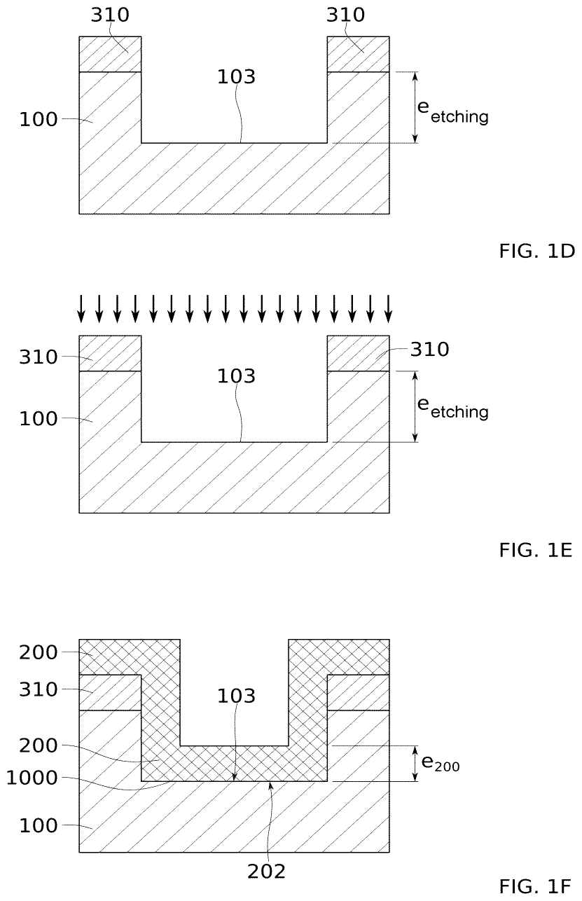

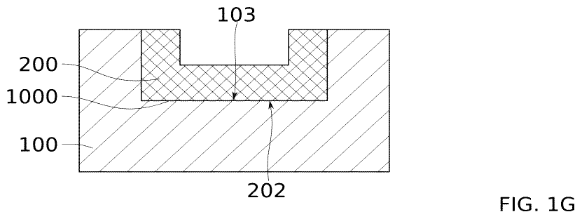

A preferably orthonormal system, comprising the axes x, y, z is represented in FIG. 1A. This system is applicable by extension to the other figures.

In the present patent application, preferably thickness will be referred to for a layer, and preferably height will be referred to for a structure or a device. The thickness is taken along a direction normal to the main extension plane of the layer, and the height is taken perpendicularly to the base plane XY. Thus, a layer typically has a thickness along z, when it extends mainly along a plane XY, and a projecting element, for example, an isolation trench, has a height along z. The relative terms “on”, “under”, “underlying” preferably refer to positions taken along the direction z.

The steps of the method such as claimed are understood in the broad sense, and can optionally be carried out in several substeps.

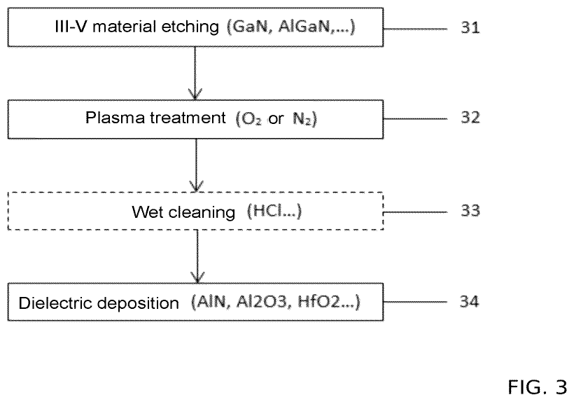

An example of the production method will now be described in reference to FIGS. 1A to 1G and to FIG. 3. This method makes it possible to obtain the structure illustrated in FIG. 1G, comprising an interface 1000 between an etched III-V material layer 100 and a dielectric layer 200.

As illustrated in FIG. 1A, a first step consists of providing a layer 100 with the basis of at least one III-V material, preferably with the basis of at least one III-N material. Typically, this material is GaN-based. This layer is called III-V layer 100. The III-V layer 100 has an upper face 101 and a lower face 102, both extending mainly into the plane XY of the orthogonal system XYZ. It has, along the direction z, a thickness e₁₀₀.

The III-V layer 100 can be formed of a homogenous layer, typically of one single material. Alternatively, the III-V layer 100 can be formed of a stack of III-N material layers, at least come of these layers having a different composition. For example, the III-V layer 100 can be formed of one or more GaN layers and one or more P-, AlGaN-, AlN- and/or InGaN-doped GaN layers. Typically, the III-V layer 100 can be formed of an assembly of one or more GaN layers and of an AlGaN layer surmounting this assembly. Such is, for example, the case in certain HEMT-type transistors.

The III-V layer 100 can rest on a substrate, typically a support or growth substrate. Such a substrate is not represented in FIGS. 1A to 1G. One or more intermediate layers can be disposed between the substrate and the lower face 102 of the III-V layer 100. This can, in particular, be a nucleation layer.

A second step consists of etching at least one part of the III-V layer 100 from its upper face 101 and on a thickness e_{etching}. This step is represented by the block 31 of FIG. 3. The etching is advantageously carried out, so as to etch the III-V layer 100 on a thickness e_{etching} greater than 100 nm (10⁻⁹ metres), preferably greater than 500 nm, preferably greater than 1 μm (10⁻⁶ metres), preferably greater than 3 μm. In order to etch only certain zones of the III-V layer 100, it can be provided to form a mask 310 surmounting the III-V layer 100, as illustrated in FIG. 1C. The presence of this mask 310 is however not compulsory to implement the etching method described below. According to an example, the mask 310 is disposed, directly in contact with the upper face 101 of the III-V layer 100. The mask 310 is, for example, formed by lithography of a masking layer 300 deposited or transferred onto the III-V layer 100, as illustrated in FIG. 1B. Preferably, the mask 310 is a hard mask. It is preferably with the basis of a polymer, for example, a resin, or a dielectric. It is, for example, formed with the basis of SiO₂ or of SiₓN_{y} with x and y non-zero integers. The hard mask 310 can, for example, be formed by one of the following materials, or a mixture of several of the following materials: SiN, Si₃N₄, SiOCN, SiCBN. The mask 310 has at least one opening 311, as illustrated in FIG. 1C, through which the etching of the III-V layer 100 is carried out.

The etching can be a dry or wet etching. For example, this can be a chlorine or fluorocarbon chemistry plasma etching step. This etching step can be carried out in a reactive ion etching (RIE) reactor, preferably an inductively coupled plasma (ICP) reactor. It is also possible to implement a self-limiting cyclic etching method, such as ALE (atomic layer etching), individually or complementarily to a conventional plasma etching. Such a method is generally constituted of one or more cycles comprising the following steps:
A step of modifying a part of the layer to be etched preferably located on the surface of this same layer, for example, a self-limiting chlorination by exposure to a plasma of Cl₂/BCl₃,
An etching of the part of the layer to be etched thus modified selectively to the rest of the layer to be etched, for example using an Ar-based plasma and under a non-zero bias voltage.
   Self-limiting cyclic etching methods make it possible to significantly limit the damage to the etched layer. In synergy with the plasma treatment step which will be described below, a step of etching the III-V layer 100 via such a method makes it possible to obtain a further improved interface 1000 quality. It is, however, absolutely possible that the step of etching the III-V layer 100 is limited to a conventional plasma etching.

The etching techniques mentioned above are given as examples, but do not constitute, in any case, an exhaustive list of techniques which can be considered.

The etching step having just been described makes it possible to expose a surface called etched surface 103 of the III-V layer 100, as represented in FIG. 1D. According to an example, this etching makes it possible, for example, to form a trench in the III-V layer 100.

A third step consists of the exposure of the etched surface 103 to a treatment as represented in FIG. 1E. The treatment is featured on this diagram by vertical arrows oriented towards the etched surface 103. This treatment is by a dioxygen (O₂)- and/or dinitrogen (N₂)-based plasma. This step is represented by the block 32 of FIG. 3. It is advantageously carried out in the same chamber as the step of etching the III-V layer 100. This is preferably an ICP reactor. Carrying out the plasma treatment step in situ makes it possible to limit the contaminations due to the venting of the samples and to improve productivity. This also has an advantage in line with the structural defects induced by the etching step. Indeed, following the etching step, the etched surface 103 constitutes a reactive surface which, during a venting, reacts with air to form defects. For example, gaps caused by the etching at the etched surface 103 can be filled with contaminants present in air, such as carbon- or oxygen-based contaminants. The latter thus constitute traps being able to impede the step of depositing a dielectric which will be detailed above and/or alter the electronic performance of a device obtained after additional subsequent steps. Subjecting the etched surface 103 to the plasma treatment in situ and before any venting of the sample, makes it possible to fill these gaps with advantageous elements provided by the plasma, and thus limit the filling of these same gaps with elements present in air. For example, the nitrogen gaps of a GaN-based etched surface 103 can be filled with nitrogen atoms provided by an N₂-based plasma treatment.

It is, however, possible to carry out the plasma treatment in a chamber which is distinct from that used for the etching of the III-V layer 100.

The flow of O₂ or N₂ is generated in the treatment chamber by a source, the power of which is between 100 W and 4000 W, preferably between 300 W and 1000 W. The power of the flow is a parameter having a direct impact on the reactivity of the plasma formed. In the scope of the present invention, it is sought to obtain a highly chemically reactive plasma in order to ensure the good reconstitution of the etched surface 103, and this, in reduced treatment times. This is characterised, in particular, by a high reactive radical concentration, and a limited quantity of ions. Increasing the power of the flow makes it possible to increase the quantity of reactive radicals, but also has the impact of increasing the density of ions.

The preferable values mentioned thus constitute a good compromise. The flow can be pure or be mixed with other minor gases. For example, this can be a flow composed of N₂ and of O₂, of N₂ and of Ar, or also of O₂ and of Ar. The flow rate of the species is advantageously between 50 sccm and 1000 sccm (cubic centimetres per minute), preferably between 100 sccm and 500 sccm. The duration of this plasma treatment step is advantageously between a few seconds, preferably 30 s, and several hundreds of seconds. The bias voltage is preferably zero. Indeed, opting for a non-zero bias voltage, combined with the fact that the plasma contains ions, increases the risk of degradation.

The plasma treatment step takes place at a temperature of less than 100° C. and not at a high temperature, as is the case for current techniques of recrystallising an etched layer. This treatment condition has made it possible to improve, in unexpected proportions, the quality of the interface 1000. This low temperature level makes it possible, in particular, to obtain a stabilised interface 1000 after the plasma treatment step. This makes it possible to improve the robustness of the method, and therefore the quality of the interface, while improving productivity. In addition, in the case of an O₂-based plasma treatment, the low-temperature work makes it possible to avoid an undesired oxidation on the etched surface 103.

Preferably, the treatment temperature, i.e. the temperature of the substrate carrier on which the III-V layer 100 rests in the plasma treatment chamber is greater than 20° C. Preferably, it is less than 90° C. Advantageously, it is between 40° C. and 80° C., preferably between 60° C. and 80° C. Increasing the temperature makes it possible, in particular, to improve the reactivity of the etched surface 103, and therefore to optimise the structural reconstruction of the III-V layer 100.

Advantageously, but optionally, a wet cleaning of the etched surface 103 of the III-V layer 100 is provided after the step of exposure to the plasma treatment. This cleaning is advantageously HCl, HF-based, or with the basis of an HCl and HF mixture. This step makes it possible to clean the etched surface ahead of the deposition of a dielectric layer 200 and constitutes a complement to the plasma treatment. It also makes it possible to improve the electric properties of the interface between the etched III-V layer 100 and the dielectric layer 200. These electric properties are improved in a surprising measure. This cleaning step is carried out outside of the reactor having enabled the etching of the III-V layer 100. This optional step is represented by the block 33, drawn in a dotted line, of FIG. 3.

A fourth step, represented in FIG. 1F and by the block 34 of FIG. 3, consists of the deposition of a layer with the basis of a dielectric material at least one the etched surface 103 of the III-V layer 100. This layer is called dielectric layer 200. Preferably, it is constituted of a dielectric material taken from among one of the following materials, or from a mixture of these: AlN, Al₂O₃, HfO₂. Preferably, the deposition of the dielectric layer 200 is carried out by ALD (atomic layer deposition). This can be a thermal or plasma ALD method. In the particular case where the dielectric layer 200 is an Al₂O₃ layer, and where the deposition of carried out by thermal ALD, the oxygen-based precursor can be water (H₂O) or ozone (O₃), and the aluminium-based precursor can be trimethylaluminum (TMA). If the deposition is carried out by plasma ALD, the oxygen-based precursor can be a dioxygen (O₂)-based plasma. The deposition of the dielectric layer 200 is preferably carried out under vacuum, in order to avoid contaminations.

The contact zone between the lower face 202 of the dielectric layer 200 and the etched surface 103 of the III-V layer 100 constitutes the interface 1000 between the III-V layer 100 and the dielectric layer 200.

FIG. 1G illustrates an optional step of removing the mask 310 and certain portions of the dielectric layer 200. This removal can take place before or after the step of exposing the etched surface 103 to the plasma treatment and before or after the step of depositing the dielectric layer 200. This removal can, for example, be simultaneous with the cleaning step. In this case, an HF- or HCl and HF-based solvent is preferably used. Advantageously, the mask 310 is preserved until the step of exposing to the plasma treatment, during which it can act as a mask. The mask 310 can also be preserved until the step of depositing the dielectric layer 200, as illustrated in FIG. 1F.

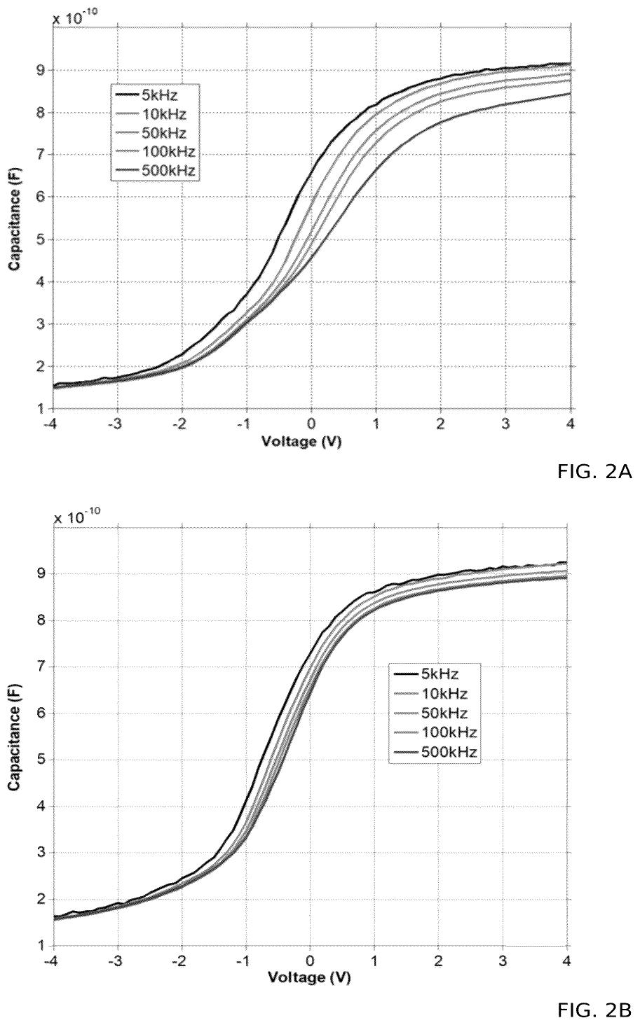

FIGS. 2A and 2B illustrate one of the advantages provided by the method according to the invention. The graph presented in FIG. 2A is a C-V (capacitance-voltage) feature of an MOS capacitance comprising an interface between an etched GaN layer and an Al₂O₃ layer and obtained by a method not including plasma treatment subsequent to the etching of the GaN layer. The graph presented in FIG. 2B is a C-V feature of an MOS capacitance having been designed by the same method and with the same materials, but the etched GaN layer of which has undergone a plasma treatment in an ICP reactor, as well as an HCl-based wet cleaning, according to one of the embodiments of the invention. In each of the two FIGS. 2A and 2B, the C-V feature has been identified for different frequencies of the alternating signal applied to the MOS capacitance studied.

It is noted that, in particular with a low frequency (see in particular, the 5 kHz feature) and with a high frequency (see in particular, the 500 kHz feature), the MOS capacitance characterised in FIG. 2A has a lower performance than the MOS capacitance characterised in FIG. 2B. The slopes of the features for each of the frequencies studied are indeed lower than their equivalents in FIG. 2B, conveying a slower passage of the accumulation regime to the inversion regime in response to a voltage variation. The comparison of FIGS. 2A and 2B therefore highlights a clear improvement, thanks to the method according to the invention of the performance of electronic components comprising an etched III-V material/dielectric interface.

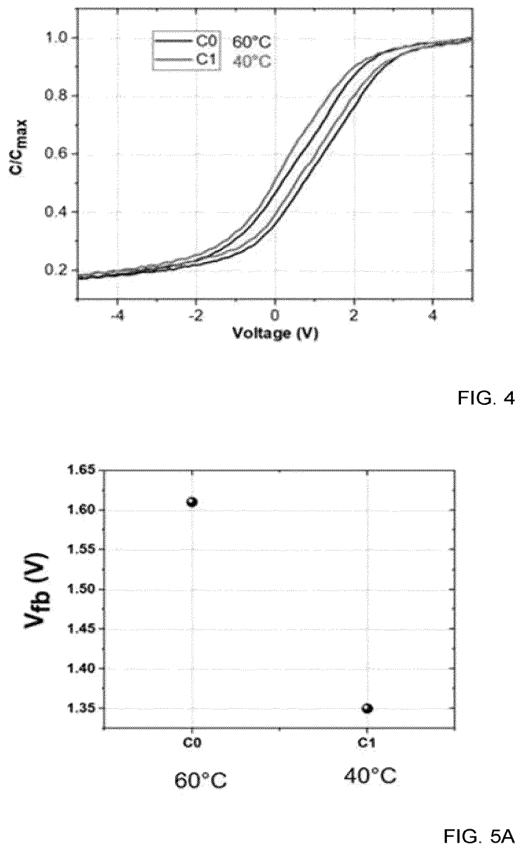

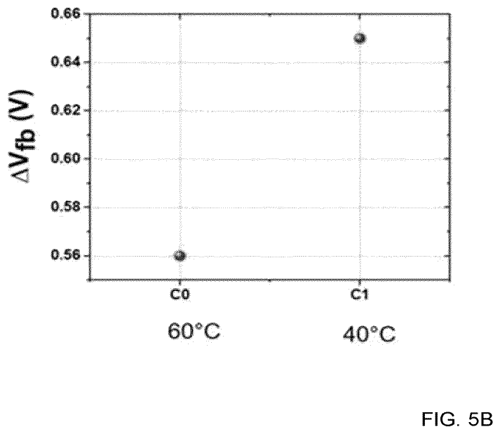

FIGS. 4, 5A and 5B illustrate the fact that, as expressed above, the choice of the treatment temperature makes it possible to optimise the performance of the devices produced according to the invention. The graph presented in FIG. 4 is a C-V feature of an MOS capacitance comprising an interface between a dielectric and a III-V material obtained by implementation of an embodiment of the method according to the invention, and this, for two distinct treatment temperatures: 40° C. and 60° C. FIGS. 5A and 5B illustrate the value of the flat band voltage Vfb and of the hysteresis ΔVfb for each of these two samples. It is observed that the MOS capacitance having undergone a treatment at a temperature of 60° C. has a better electric performance than that of which the treatment temperature was 40° C. In particular, its flat band voltage is greater (around 1.61V against 1.35V for Tₜᵣₑₐₜₘₑₙₜ=40° C.), while its hysteresis is clearly less (around 0.56V against 0.65V for Tₜᵣₑₐₜₘₑₙₜ=40° C.). Increasing, in a certain measure, the treatment temperature during the plasma treatment step therefore enables a clear improvement of the performance of the device, which is explained by a better resorption of the surface defects.

It has been noted, however, that surprisingly, for temperatures going beyond 80° C., the performance of the MOS capacitances were greatly and rapidly degraded. This illustrates the fact that treating a high, even very high temperature sample, hoping for a better recrystallisation, as is commonly achieved, is not always useful. A recrystallisation which is too rapid can, on the contrary, freeze structural defects, in particular on the surface, thus inducing a degradation of the performance of the devices.

These results thus illustrate the optimisation of the structural reconstruction of the III-V layer in the 60° C.-80° C. range.

An advantage of the solution proposed by the invention, is that the steps of exposing to a plasma treatment of the etched III-V layer 100 and of depositing a dielectric layer 200 can be carried out after any type of etching and for any III-V material. The method according to the invention therefore constitutes a solution that could be qualified as universal against the problem of quality of interfaces between an etched III-V material and a dielectric. Such an adaptability in addition enables a certain standardisation of the methods for manufacturing electronic components in which the method according to the invention can be integrated.

Another advantage of the solution proposed is that the plasma treatment step is a rapid step being able to, in addition, be carried out immediately after the etching step, in the same reactor. The method according to the invention can thus be integrated to a method for manufacturing microelectronic devices without altering productivity.

Through the different embodiments described above, it clearly appears that the invention proposes an effective solution for improving the productivity of the formation of an interface between an etched III-V material layer and a dielectric layer, while ensuring a good quality of this interface.

The method proposed is particularly advantageous for power applications, such as power transistors or LEDs or μLEDs. In this case, the III-V material thickness to be etched, such as GaN, can be from one hundred nanometres to several microns.

The invention is not limited to the embodiments described above, and extends to all the embodiments covered by its spirit.

1. A method for forming a layer based upon a dielectric material on a layer based upon an etched III-V material, comprising:
providing at least one III-V layer based upon a III-V material, having a front face,
etching at least one part of the III-V layer from the front face, so as to expose an etched surface of the III-V layer,
exposing at least the etched surface to a plasma treatment of O₂, of N₂ or of a mixture of O₂ and of N₂, at a temperature Tₜᵣₑₐₜₘₑₙₜ of between 60° C. and 80° C., and
depositing a dielectric layer based upon a dielectric material, at least on the etched surface.

2. The method according to claim 1, wherein the etching and the exposing are carried out in one same reactor.

3. The method according to claim 1, wherein the exposing has a duration tₜᵣₑₐₜₘₑₙₜ, with tₜᵣₑₐₜₘₑₙₜ<5 min.

4. The method according to claim 1, further comprising, before depositing the dielectric layer, a wet cleaning step.

5. The method according to claim 1, wherein depositing the dielectric layer is carried out under vacuum.

6. The method according to claim 1, wherein the etching comprises a chlorine plasma etching.

7. The method according to claim 1, wherein the etching comprises at least one ALE-type etching cycle.

8. The method according to claim 1, wherein the exposing is carried out under a zero bias voltage.

9. The method according to claim 1, wherein the etching is carried out, so as to etch a III-V material thickness greater than 100 nm (10⁻⁹ metres).

10. The method according to claim 1, wherein the exposing is carried out by injecting a flow of O₂, of N₂ or of a mixture of O₂ and of N₂, having a mass flow of between 50 sccm and 1000 sccm.

11. The method according to claim 1, wherein the exposing is carried out by injecting a flow of O₂, of N₂ or of a mixture of O₂ and of N₂ generated by a power source of between 100 W and 4000 W.

12. The method according to claim 1, wherein the III-V material is one from among GaN and AlGaN.

13. The method according to claim 1, wherein the dielectric material is one from among AlN, Al₂O₃ and HfO₂.

14. A method for producing a microelectronic device comprising forming a layer based upon the dielectric material on a layer based upon an etched III-V material by implementing the method according to claim 1, the microelectronic device being taken from among a transistor and an LED.

15. The method for producing a microelectronic device according to claim 14, wherein:
the microelectronic device is a transistor,
the etching of the III-V layer is carried out, so as to produce a trench in the etched III-V material,
depositing the layer based upon the dielectric material is carried out on at least one part of an etched surface of the trench, so as to form a gate dielectric,
the method comprising, after forming the dielectric layer, filling the trench to define at least one gate of the transistor.

16. The method according to claim 1, wherein the III-V material is a III-N material.

17. The method according to claim 1, wherein the exposing has a duration tₜᵣₑₐₜₘₑₙₜ, with tₜᵣₑₐₜₘₑₙₜ<2 min.

18. The method according to claim 1, wherein the etching is carried out, so as to etch a III-V material thickness greater than 1 μm (10⁻⁶ metres).

19. The method according to claim 1, wherein the exposing is carried out by injecting a flow of O₂, of N₂ or of a mixture of O₂ and of N₂, having a mass flow of between 100 sccm and 500 sccm.

20. The method according to claim 1, wherein the exposing is carried out by injecting a flow of O₂, of N₂ or of a mixture of O₂ and of N₂ generated by a power source of between 300 W and 1000 W.
